(19) United States
(12) Patent Application Publication
(10) Pub. No.: US 2006/0097322 A1
(43) Pub. Date: May 11, 2006

(54) Electrostatic discharge (ESD) protection circuit

(76) Inventors: Kook-Whee Kwak, Kyoungki-do (KR); Sang-Yong Kim, Kyoungki-do (KR)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/272,570

(22) Filed: Nov. 9, 2005

(30) Foreign Application Priority Data
Nov. 10, 2004 (KR) 2004-0091537

(51) Int. Cl. H01L 23/62

(52) U.S. Cl. 257/355

(57) ABSTRACT

An electrostatic discharge (ESD) protection circuit is provided. The ESD protection circuit includes: a first conductivity type substrate; a second conductivity type well region formed in a predetermined portion of the substrate; a gate structure including a gate insulation layer and a gate electrode stacked on a selected surface portion of the substrate and separated from the well region with a predetermined distance; a first conductivity type first diffusion region formed in the well region; a second conductivity type second diffusion region formed beneath another selected surface portion of the substrate contacting one side edge of the gate structure; and a second conductivity type third diffusion region, extending from the other side edge of the gate structure into the well region, and electrically connected to the first diffusion region through a resistor.

### FIELD OF THE INVENTION

The present invention relates to a semiconductor device; and more particularly, to an electrostatic discharge (ESD) protection circuit having a low-voltage triggering silicon controlled rectifier (LVTSCR) structure.

### DESCRIPTION OF RELATED ARTS

A diode, a metal oxide semiconductor (MOS) transistor and a low-voltage triggering silicon controlled rectifier (LVTSCR) device have been widely used as an electrostatic discharge (ESD) protection circuit for a semiconductor device circuit.

The diode provides advantages that the ESD current which the diode can allow per unit area is high and junction capacitance is small. However, the diode provides a large operation resistance and is limited to be independently used. As for the transistor, the triggering voltage and operation resistance are low; however, the ESD current that the transistor can allow per unit area is only ⅓ to ⅕ of the ESD current level that the diode or the SCR can allow per unit area. Thus, since the transistor should use relatively large area in order to satisfy a predetermined ESD level, the transistor provides a disadvantage that the junction capacitance gets greater. Compared with the diode and the transistor, the LVTSCR device provides advantages that operation resistance is low, and junction capacitance is small as the ESD current that the LVTSCR device can allow per unit area is high. However, the LVTSCR device provides a disadvantage that it is hard to be used for high-speed and low-voltage circuits because the triggering voltage of the LVTSCR device is high and unstable compared with that of the transistor while an ESD event occurs.

FIG. 1 is a diagram illustrating a conventional LVTSCR structure used as an ESD protection circuit. The LVTSCR shown in FIG. 1 is published in an article by A. Chatterjee and T. Polgreen, entitled “A Low-Voltage Triggering SCR for On-Chip ESD Protection at Output and Input Pads”, IEEE Electron Devices Letters, Volume 12, pp. 21-22, 1991.

As shown in FIG. 1, a gate insulation layer 150 and a gate electrode 152 are sequentially formed on a selected surface portion of a substrate 110 doped with a P-type impurity. A first diffusion region 130 and a second diffusion region 132 doped with an N-type impurity are formed beneath another selected surface portion of the substrate 110 and contacted to both ends of the gate electrode 152. A well region 120 doped with an N-type impurity is formed by extending from a predetermined portion of the substrate 110 into a predetermined portion of the second diffusion region 132. Inside of the well region 120, a third diffusion region 134 doped with a P-type impurity and a fourth diffusion region 136 doped with an N-type impurity are formed alongside of each other. The third diffusion region 134 is separated from the second diffusion region 132 by a device isolation layer 140.

The gate electrode 152 and the first diffusion region 130 are connected to a ground Vss and the third diffusion region 134 and the fourth diffusion region 136 are connected to an input/output pad I/O PAD.

As shown in FIG. 1, the SCR is formed in a PNPN structure formed with the P-type third diffusion region 134 connected to the input/output pad I/O PAD, the N-type well region 120, the P-type substrate 110 and the N-type first diffusion region 130 connected to the ground Vss.

As the ESD voltage induced to the input/output pad I/O PAD during an ESD event is abruptly increased, voltages of the well region 120 directly connected to the input/output pad I/O PAD and the second diffusion region 132 are simultaneously increased. Thus, a strong reverse bias voltage is applied at the PN junction composed of the second diffusion region 132 and the substrate 110. If the bias voltage due to the ESD event exceeds avalanche breakdown voltage of the PN junction, then junction breakdown occurs, and the ESD current flows into the substrate 110 through the well region 120, discharging the ESD current to the ground Vss through the first diffusion region 130. That is, an operation of a second parasitic bipolar transistor Q2 172 formed with the well region 120, the substrate 110 and the first diffusion region 130 gets triggered.

Current I flowing into the ground Vss through the second parasitic bipolar transistor Q2 172 from the fourth diffusion region 136 by the operation of the second parasitic bipolar transistor Q2 172 generates a potential difference corresponding to a drop of I×R_{NWELL} between the third diffusion region 134, which is emitter of the first parasitic bipolar transistor Q1 170, and the well region 120 which is base of the first parasitic bipolar transistor Q1 170, thereby triggering an operation of the first parasitic bipolar transistor Q1. Herein, R_{NWELL} indicates the resistance of the well region 120.

In other words, since collector of the second parasitic bipolar transistor Q2 172 corresponds to the base of the first parasitic bipolar transistor Q1 170, the current I flowing into the second parasitic bipolar transistor Q2 172 supplies a current to the base of the first parasitic bipolar transistor Q1 170, thereby triggering the operation of the first parasitic bipolar transistor Q1 170.

Thereafter, as for the first parasitic bipolar transistor Q1 170 and the second parasitic bipolar transistor Q2 172 of which the collector of one transistor is the base of the other transistor, operation of one transistor reciprocally promotes operation of the other transistor. Accordingly, it is possible to perform a highly efficient ESD operation providing a low operation resistance and allowing a large ESD current with only a small layout area.

However, the operation of the SCR shown in FIG. 1 depends on various parameters such as the avalanche breakdown voltage and current of the NP junction, the resistance of the N-type well region 120 R_{NWELL} and the resistance of the substrate R_{SUB}. Thus, compared with the parasitic bipolar transistor of a typical MOS transistor, the SCR has disadvantages that the operation triggering voltage is high and unstable.

A conventional technology suggested to settle the high operation triggering voltage and the degradation in the stability of the LVTSCR device is illustrated in FIG. 2.

FIG. 2 is a diagram illustrating another conventional LVTSCR structure. The other conventional LVTSCR structure is published in the U.S. Pat. No. 6,492,208.

As shown in FIG. 2, a plurality of gate insulation layers 250 are formed on selected surface portions of a substrate 210 doped with a P-type impurity and a plurality of gate electrodes 252 are formed thereon. A plurality of first diffusion regions 230 and a plurality of second diffusion regions 232 doped with N-type impurities are formed beneath other selected surface portions of the substrate 210 and contacted with both ends of the gate electrodes 252.

A plurality of well regions 220 doped with N-type impurities are formed by extending from predetermined portions of the second diffusion regions 232 to other portions of the substrate 210. A plurality of third diffusion regions 234 doped with the P-type impurities are formed inside of the well regions 220 and interposed between the second diffusion regions 232.

The gate electrodes 252 and the first diffusion regions 230 are connected to a plurality of grounds Vss, and the second diffusion regions 232 and the third diffusion regions 234 are connected to an input/output pad I/O PAD.

A plurality of P⁺-type diffusion regions 238 formed on each end of the substrate 210 and connected to the grounds Vss are substrate contact regions.

As for the LVTSCR structure shown in FIG. 2, since the second diffusion regions 232 and the third diffusion regions 234 are connected to the input/output pad I/O PAD, ESD voltage added to the input/output pad I/O PAD is directly transferred to the second diffusion regions 232. Accordingly, a second parasitic bipolar transistor Q2 272 of a grounded-gate N-type metal oxide semiconductor (GGNMOS) formed with the first diffusion regions 230, the second diffusion regions 232, channels between the first diffusion regions 230 and the second diffusion regions 232 and the gate electrodes 252 just gets operated. Thus, triggering voltage of the LVTSCR structure shown in FIG. 2 is lower and more stable than that of the LVTSCR structure shown in FIG. 1.

However, as for the LVTSCR structure shown in FIG. 2, current discharged to the ground Vss passes the second parasitic bipolar transistor Q2 272 through the substrate channel region between the second diffusion region 232 and the first diffusion region 230, without flowing through the N-type well regions 220. Accordingly, it is not possible to induce a potential difference between the third diffusion regions 234, which are emitters of the first parasitic bipolar transistor Q1 270, and the well regions 220 which are bases of the first parasitic bipolar transistor Q1 270. Thus, there is a problem that the first parasitic bipolar transistor Q1 270 cannot be triggered.

That is, because during the ESD event, the operation of the SCR device cannot be triggered and only the second parasitic bipolar transistor Q2 272 operates, there is an advantage that the level of the operation triggering voltage is as low as that of the GGNMOS. However, there may be a limitation that efficiency in current conductivity can be reduced to the level of the GGNMOS which is ⅕ of that of SCR.

### SUMMARY OF THE INVENTION

It is, therefore, an object of the present invention to provide an electrostatic discharge (ESD) protection circuit having a low and stable operation triggering voltage, and high current conductivity efficiency per unit area.

In accordance with one aspect of the present invention, there is provided an electrostatic discharge (ESD) protection circuit, including: a first conductivity type substrate; a second conductivity type well region formed in a predetermined portion of the substrate; a gate structure including a gate insulation layer and a gate electrode stacked on a selected surface portion of the substrate and separated from the well region with a predetermined distance; a first conductivity type first diffusion region formed in the well region; a second conductivity type second diffusion region formed beneath another selected surface portion of the substrate contacting one side edge of the gate structure; and a second conductivity type third diffusion region, extending from the other side edge of the gate structure into the well region, and electrically connected to the first diffusion region through a resistor.

In accordance with another aspect of the present invention, there is provided an ESD protection circuit, including: a first conductivity type substrate; a second conductivity type well region formed in a predetermined portion of the substrate; a gate structure including a gate insulation layer and a gate electrode stacked on a selected surface portion of the well region; a second conductivity type first diffusion region formed in the substrate, separated from the well region with a predetermined distance; a first conductivity type second diffusion region formed in the well region in one side of the gate structure; and a first conductivity type third diffusion region, extending from the other side edge of the gate structure into the aforementioned well region, and electrically connected to the first diffusion region through a resistor.

In accordance with further aspect of the present invention, there is provided an ESD protection circuit, including: a first conductivity type substrate; a plurality of second conductivity type well regions, each formed in a predetermined portion of the substrate; a plurality of gate structures, each including a gate insulation layer and a gate electrode formed on a selected surface portion of the substrate and separated from the respective well region with a predetermined distance; a plurality of first conductivity type first diffusion regions, each formed in the respective well region and shared by neighboring transistors; a plurality of second conductivity type second diffusion regions, formed beneath another selected surface portion of the substrate in one side of the respective gate structure and shared by neighboring transistors; and a plurality of second conductivity type third diffusion regions, each extending from the other side edge of the respective gate structure into the respective well region, and electrically connected to the respective first diffusion region through a resistor.

In accordance with still further aspect of the present invention, there is provided an ESD protection circuit, including: a first conductivity type substrate; a plurality of second conductivity type well regions, each formed in a predetermined portion of the substrate; a plurality of gate structure including a gate insulation layer and a gate electrode formed on a selected surface portion of the respective well region; a plurality of second conductivity type first diffusion regions, each formed in the substrate, separated from the respective well region with a predetermined distance, shared by neighboring transistors and connected to a respective ground; a plurality of first conductivity type second diffusion regions, each connected to an input/output pad, formed in the respective well region in one side of the respective gate structure and shared by neighboring transistors; and a plurality of first conductivity type third diffusion regions, each extending from the other side edge of the respective gate structure into the respective well region, and electrically connected to the respective first diffusion region through a resistor.

### BRIEF DESCRIPTION OF THE DRAWINGS

The above and other objects and features of the present invention will become better understood with respect to the following description of the preferred embodiments given in conjunction with the accompanying drawings, in which:

FIG. 1 is a cross-sectional view illustrating a conventional low-voltage triggering silicon controlled rectifier (LVTSCR) structure used as an electrostatic discharge (ESD) protection circuit;

FIG. 2 is a cross-sectional view illustrating another conventional LVTSCR structure;

FIG. 3 is a cross-sectional view illustrating an ESD protection circuit having a LVTSCR structure in accordance with a first embodiment of the present invention;

FIG. 4A is a simulation result illustrating the flow of current through the LVTSCR structure shown in FIG. 2;

FIG. 4B is a simulation result illustrating the flow of current through the LVTSCR structure shown in FIG. 3;

FIG. 5A is simulation result illustrating the temperature contour due to heat generated by a flow of ESD current in the LVTSCR structure shown in FIG. 2;

FIG. 5B is simulation result illustrating the temperature contour due to heat generated by a flow of ESD current in the LVTSCR structure shown in FIG. 3;

FIG. 6 is a cross-sectional view illustrating an ESD protection circuit having a LVTSCR structure in accordance with a second embodiment of the present invention;

FIG. 7 is a cross-sectional view illustrating an ESD protection circuit having a LVTSCR structure in accordance with a third embodiment of the present invention; and

FIG. 8 is a cross-sectional view illustrating an ESD protection circuit having a LVTSCR structure in accordance with a fourth embodiment of the present invention.

### DETAILED DESCRIPTION OF THE INVENTION

A method for fabricating a semiconductor device in accordance with a specific embodiment of the present invention will be described in detail with reference to the accompanying drawings.

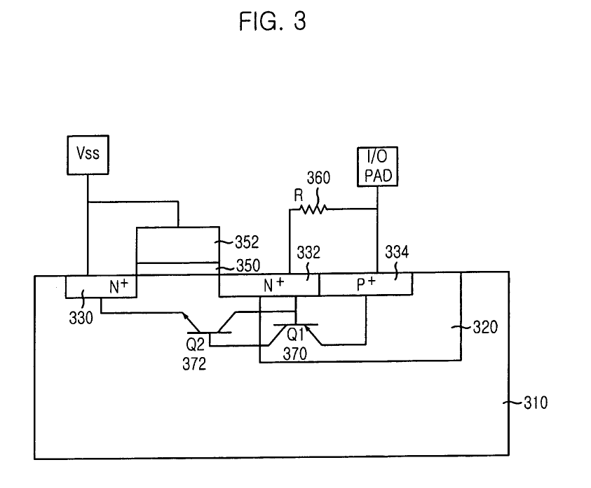

FIG. 3 is a cross-sectional view illustrating a low-voltage triggering silicon controlled rectifier (LVTSCR) structure used as an electrostatic discharge (ESD) protection circuit in accordance with a first embodiment of the present invention.

As shown in FIG. 3, a first conductivity type substrate 310 having a second conductivity type well region 320, a gate insulation layer 350 and a gate electrode 352 stacked on a selected surface portion of the substrate 310 and separated from the well region 320 with a predetermined distance (herein, the gate insulation layer 350 and the gate electrode 352 configure a gate structure), a first diffusion region 334 formed inside of the well region 320, a second diffusion region 330 formed beneath another selected surface portion of the substrate 310 in one side of the gate electrode 352, and a third diffusion region 332 extending from another portion of the substrate 310 to the well region 320 beneath another surface portion of the substrate 310 in the other side of the gate electrode 352 and connected to an input/output pad I/O PAD through a resistor 360.

Herein, the first diffusion region 334 and the third diffusion region 332 may or may not be in contact with each other. The gate electrode 352 and the second diffusion region 330 are connected to the ground Vss and the first diffusion region 334 is directly connected to the input/output pad, differently from the third diffusion region 332 which is connected to the input/output pad I/O PAD through the resistor 360. Also, the second diffusion region and the gate electrode can be electrically connected to the ground Vss, and the first diffusion region can be electrically connected to a power pad. Furthermore, the second diffusion region and the gate electrode can be electrically connected to the input/output pad I/O PAD, and the first diffusion region can be electrically connected to the power pad.

The first conductivity type includes a P-type impurity and the second conductivity type includes an N-type impurity. The second diffusion region 330 and the third diffusion region 332 are diffusion regions doped with highly concentrated N-type N⁺ impurities and the first diffusion region 334 is a diffusion region doped with a highly concentrated P-type P⁺ impurity.

The resistor 360 is an important element of the present invention. If a size of the resistance is too small, a potential difference between the base and emitter of the first parasitic bipolar transistor Q1 380, which is large enough to trigger an operation of the first parasitic bipolar transistor Q1 380 is not generated. Thus, the size of the resistance should be maintained at a size larger than a predetermined value. As a result of fabricating a LVTSCR structure similar to that of the present invention and measuring the size of the resistance, it is shown that if the size of the resistance of the resistor 360 of a deep submicron device is approximately 1 Ω or larger, the SCR operation is triggered. The aforementioned resistor 360 can be formed by using metal, polysilicon, or a diffusion region formed by doping an impurity on the substrate. Hereinafter, resistors used in accordance with the second to the fourth embodiments of the present invention have the same size of the resistance as the aforementioned value.

As described above in accordance with the first embodiment of the present invention, the third diffusion region 332 serving a role of a drain of a transistor is connected to the input/output pad I/O PAD through the resistor 360 having the predetermined size of the resistance, and the first diffusion region 334 is directly connected to the input/output pad I/O PAD.

The second diffusion region 330 corresponding to the source of a transistor is connected to the ground Vss along with the gate electrode 352.

As described above, the first diffusion region 334 connected to the input/output pad I/O PAD, the well region 320 and the substrate 310 form a PNP type first parasitic bipolar transistor Q1 370. The well region 320, the substrate 310 and the second diffusion region 330 form an NPN type second parasitic bipolar transistor Q2 372. Accordingly, the first parasitic bipolar transistor Q1 370 and the second parasitic bipolar transistor Q2 372 together form the PNPN type SCR. The third diffusion region 332 existing inside of the PNPN type SCR, the second diffusion region 330, a channel region existing between the third diffusion region 332 and the second diffusion region 330, and the gate electrode 352 form an N-type gate grounded metal oxide semiconductor (GGNMOS) transistor. Herein, the third diffusion region 332 serves a role of the drain and the second diffusion region 330 serves a role of the source.

If an ESD voltage is applied to the input/output pad I/O PAD due to an ESD event, an operation of the GGNMOS formed with the third diffusion region 332, the second diffusion region 330 and the gate electrode 352 is stably triggered at a low voltage since the third diffusion region 332 is connected to the input/output pad I/O PAD. If an ESD current I flows through the operation of the GGNMOS, a potential difference as much as an IR voltage drop between the emitter, i.e., the first diffusion region 334, and the base, i.e., the well region 320, of the first parasitic bipolar transistor Q1 370 is generated due to resistance R of the resistor 360 existing between the input/output pad I/O PAD and the third diffusion region 332. Thus, the operation of the SCR starts as the operation of the first parasitic bipolar transistor Q1 370 is triggered. That is, the first parasitic bipolar transistor Q1 370 and the second parasitic bipolar transistor Q2 372 are constituent elements of the PNPN type SCR device formed with the first diffusion region 334, the well region 320, the substrate 310 and the second diffusion region 330, and collector of one transistor is base of the other transistor and vice versa. Thus, an operation of one transistor triggers operation of the other transistor. Accordingly, it is possible that the SCR efficiently operates with high current carrying ability and low operation resistance.

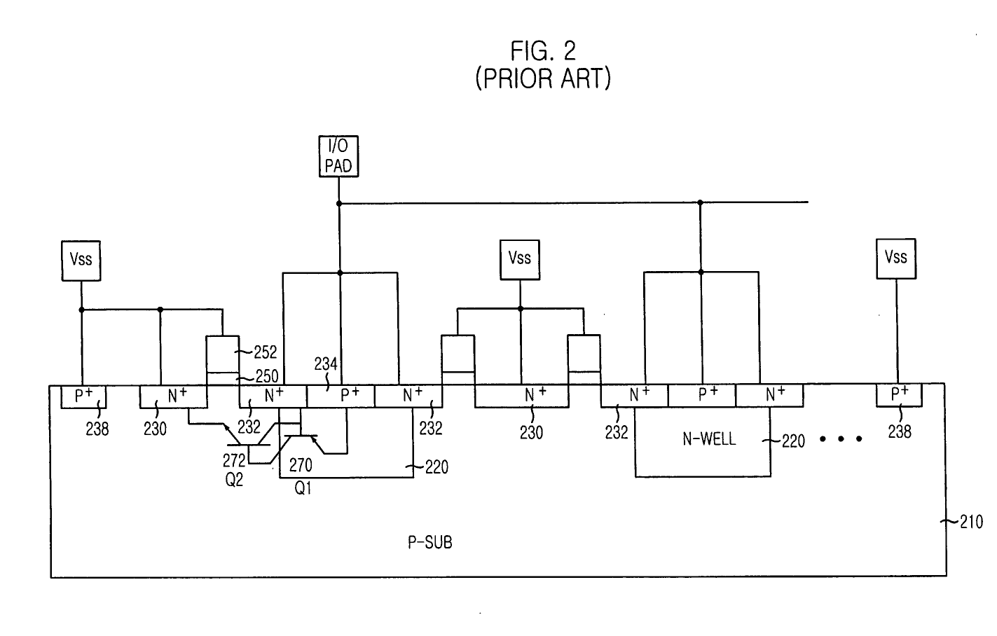

Accordingly, in accordance with the first embodiment of the present invention, the resistor 360 between the third diffusion region 332 and the first diffusion region 334 generates the potential difference between the emitter and the base of the first parasitic bipolar transistor Q1 370, thereby triggering the operation of the LVTSCR. The first embodiment of the present invention as described above is differentiated from the other conventional LVTSCR shown in FIG. 2 which cannot trigger the operation of the LVTSCR, because the conventional LVTSCR in accordance with the second embodiment does not include the resistor 360.

As a result, because the LVTSCR structure in accordance with the first embodiment of the present invention triggers the operation of the LVTSCR by using the GGNMOS, not only the operation triggering voltage is low but also the GGNMOS operation is continued to the operation of the GGNMOS. Thus, the LVTSCR structure in accordance with the first embodiment is a structure with high current conductivity efficiency.

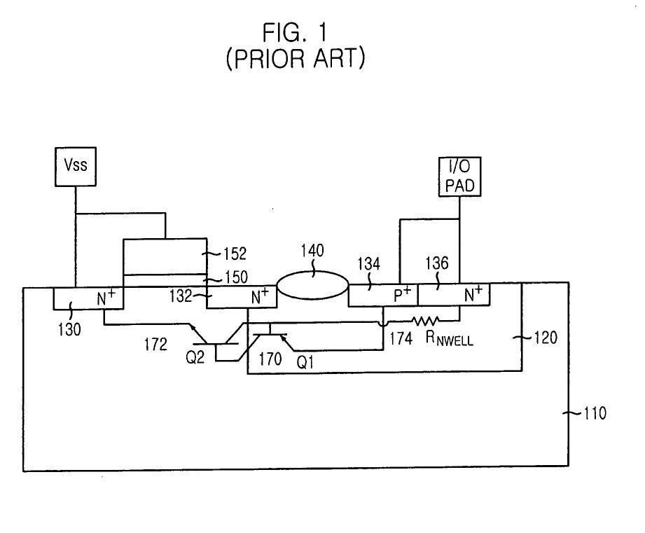

The conventional SCR structures in FIGS. 1 and 2, and the SCR structure in accordance with the first embodiment of the present invention will be compared with each other hereinafter.

First, the conventional SCR structure in FIG. 1 provides a disadvantage that the operation voltage is high since an operation of the GGNMOS doest not happen. For the conventional SCR structure shown in FIG. 2, the operation voltage is low; however, level of the current conductivity efficiency is same as that of the GGNMOS, which is no more than several tenths compared to that of the conventional SCR structure in FIG. 1.

Illustrated in Table 1 is a technology CAD (TCAD) simulation result obtained by comparing the operation triggering voltages and maximum currents, which a device can allow per unit length, of the conventional LVTSCR structures in FIGS. 1 and 2, and the LVTSCR structure in accordance with the first embodiment of the present invention.

TABLE 1

| | | The | The other |
|---|---|---|---|
| | | conventional | conventional |
| | 1^{st} Embodiment | circuit | circuit |
| | (FIG. 3) | (FIG. 1) | (FIG. 2) |
| Operation Triggering | 6.9 | 8.6 | 6.7 |
| voltage (V) | | | |
| Efficiency in | 53 | 59 | 9 |
| Current Conductivity | | | |
| per Unit Length | | | |
| (mA/μm) | | | |

As shown in Table 1, the triggering voltage of the LVTSCR structure in accordance with the first embodiment of the present invention is as low as that of the conventional LVTSCR structure in FIG. 2; while, the current conductivity efficiency has a property as good as that of the conventional LVTSCR structure in FIG. 1.

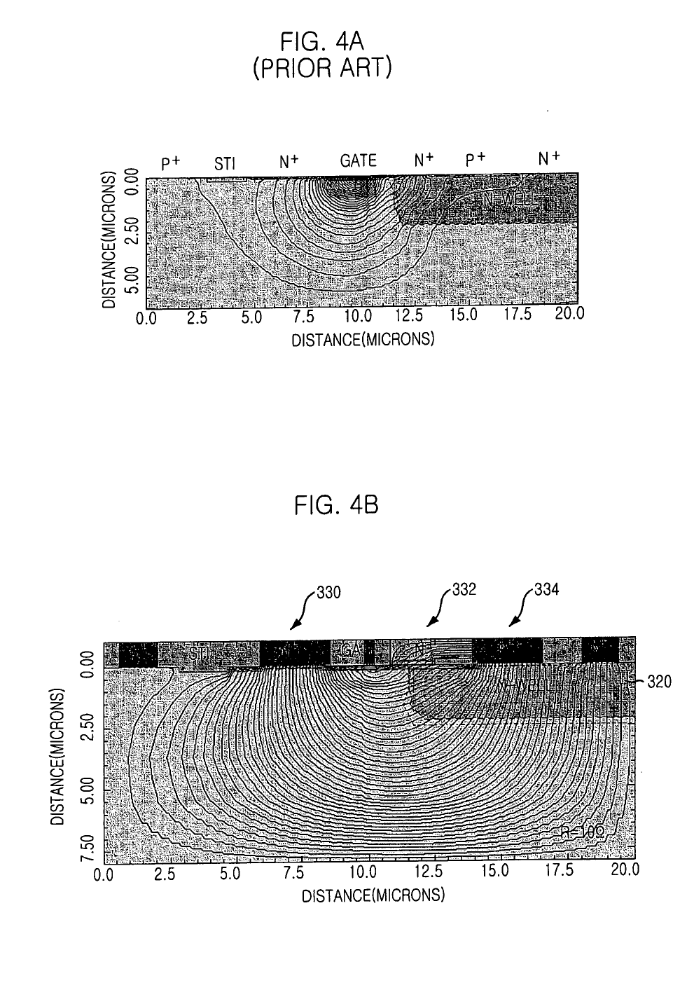

FIG. 4A and FIG. 4B are simulation results comparing current flow through the conventional LVTSCR structure in FIG. 2 and the LVTSCR structure in accordance with the first embodiment of the present invention, respectively.

As shown in FIG. 4A, in the conventional LVTSCR structure the current flows only through the GGNMOS concentrating around the gate. As described above, it is because the LVTSCR structure does not operate but only the GGNMOS does. Meanwhile, for the first embodiment of the present invention as shown in FIG. 4B, the current flows not only through the surroundings of the GGNMOS but also from the first diffusion region 334 into the well region 320. Thus, it is noticeable that the LVTSCR structure of the present invention does operate.

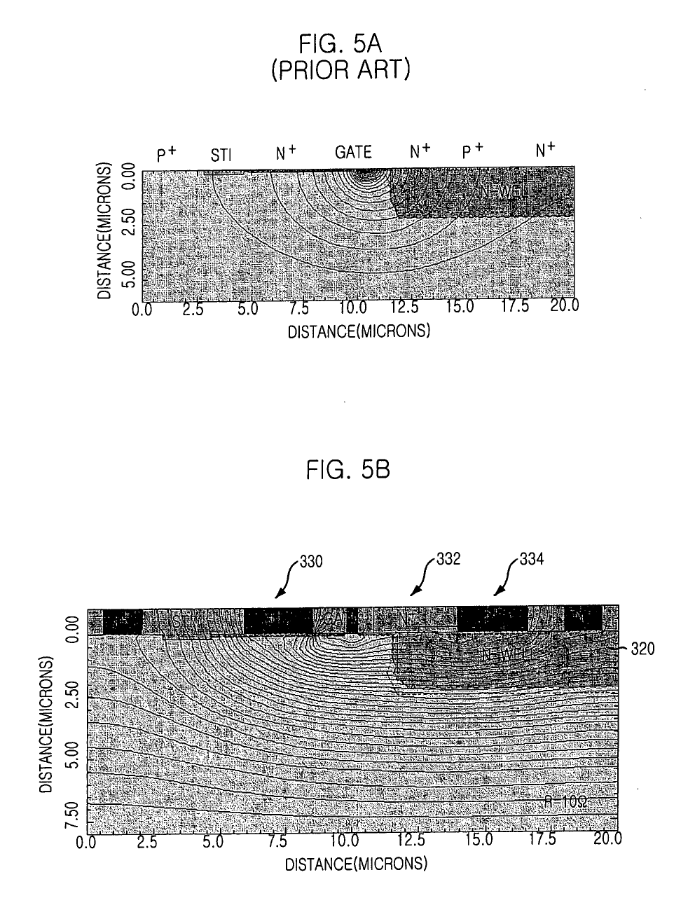

FIG. 5A and FIG. 5B are simulation results illustrating a temperature contour due to heat resulted from the ESD current flowing in the conventional LVTSCR structure in FIG. 2 and the LVTSCR structure of the first embodiment of the present invention.

For the conventional LVTSCR structure, the current concentrates around the gate of GGNMOS. Thus, temperature of the drain junction near the gate of the GGNMOS is very high as shown in FIG. 5A. Due to the high temperature of the drain junction of the GGNMOS, a defect such as a contact melting phenomenon is generated even in the relatively low ESD current.

However, as shown in FIG. 5B, for the SCR structure of the present invention, the current uniformly flows through a wide region due to the SCR triggering, a heat generation is not concentrated on only one localized area. Thus, the higher ESD current is allowable.

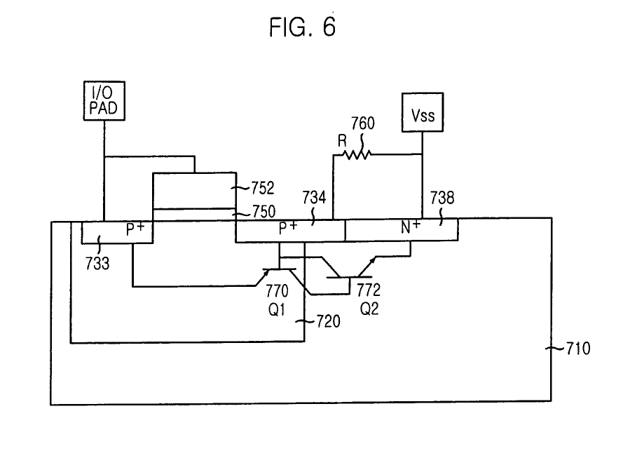

FIG. 6 is a cross-sectional view illustrating an ESD protection circuit having a LVTSCR structure in accordance with the second embodiment of the present invention.

As shown in FIG. 6, the ESD protection circuit having the LVTSCR structure in accordance with the second embodiment of the present invention includes a first conductivity type substrate 710 having a second conductivity type well region 720, a gate insulation layer 750 and a gate electrode 752 stacked on a selected surface portion of the well region 720 (herein, the gate insulation layer 750 and the gate electrode 750 configure a gate structure), a second conductivity type first diffusion region 738 formed inside of the substrate 710 and separated from the well region 720 with a predetermined distance, a first conductivity type second diffusion region 733 formed inside of the well region 720 in one side of the gate electrode 752 and connected to an input/output pad I/O PAD, and a first conductivity type third diffusion region 734 formed in a predetermined portion of the substrate 710 and connected to a ground Vss through a resistor 760.

Herein, the first diffusion region 738 and the third diffusion region 734 may or may not be in contact with each other and the gate electrode 752 is connected to the input/output pad I/O PAD.

The first conductivity type includes a P-type impurity and the second conductivity type includes an N-type impurity. The first diffusion region 738 is a diffusion region doped with a highly concentrated N-type N⁺ impurity, and the second diffusion region 733 and the third diffusion region 734 are diffusion regions doped with highly concentrated P-type P⁺ impurities.

In accordance with the second embodiment of the present invention as described above, a predetermined portion of the third diffusion region 734 corresponding to a drain is formed in the outside of the well region 720 and the third diffusion region 734 is connected to the ground Vss through the resistor 760 having a predetermined resistance value. The first diffusion region 738 is directly connected to the ground Vss.

The second diffusion region 733 corresponding to a source is directly connected to the input/output pad I/O PAD. Also, the second diffusion region and the gate electrode can be connected to a power pad and the first diffusion region can be connected to the input/output pad I/O PAD. Furthermore, the second diffusion region and the gate electrode can be connected to the power pad and the first diffusion region can be connected to the ground Vss.

As described above, the second diffusion region 733 connected to the input/output pad I/O PAD, the well region 720, the substrate 710 and the first diffusion region 738 connected to the ground Vss form a PNPN type SCR, i.e., a first parasitic bipolar transistor Q1 770 and a second parasitic bipolar transistor Q2 772. The second diffusion region 733 existing inside of the PNPN type SCR, the third diffusion region 734, a channel region existing between the second diffusion region 733 and the third diffusion region 734 and the gate electrode 752 form a P-type gate-powered metal-oxide-semiconductor (GPPMOS).

The second embodiment of the present invention as shown in FIG. 6 uses the GPPMOS which is a P-channel metal-oxide field-effect transistor (PMOSFET), thereby providing the same operating theory with the GGNMOS which is an NMOSFET of the first embodiment of the present invention shown in FIG. 3.

That is, the LVTSCR structure in accordance with the second embodiment of the present invention is triggered by using the GPPMOS. Thus, not only the operation triggering voltage is low but also the operation of the GPPMOS is continued to the operation of the LVTSCR. Accordingly, the LVTSCR structure in accordance with the second embodiment of the present invention provides high current conductivity efficiency.

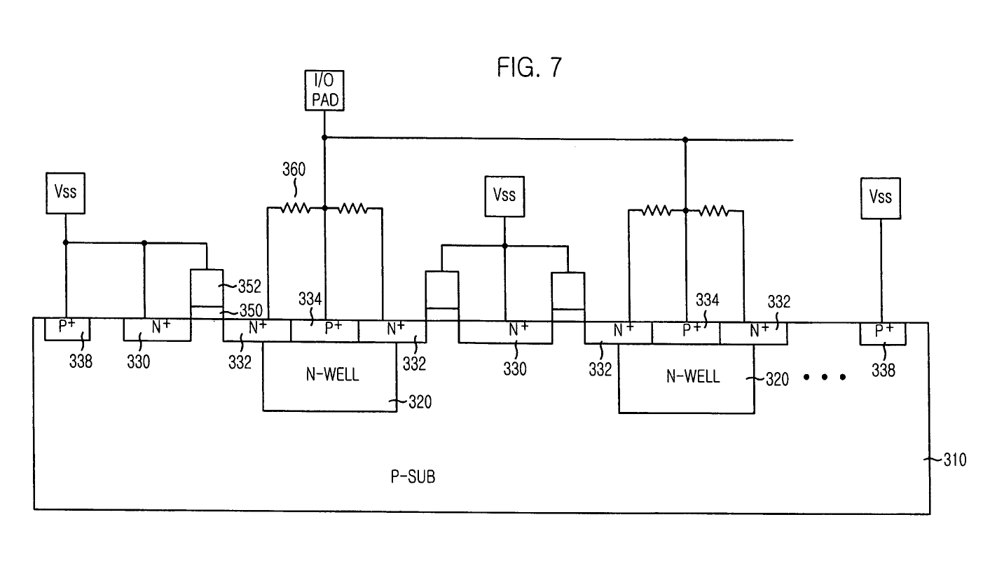

FIG. 7 is a cross-sectional view illustrating an ESD protection circuit having a LVTSCR structure in accordance with the third embodiment of the present invention. The same reference numerals used in the first embodiment of the present invention shown in FIG. 3 are used hereinafter.

As shown in FIG. 7, the ESD protection circuit having the LVTSCR structure in accordance with the third embodiment of the present invention illustrates a structure which a plurality of LVTSCR structures formed in accordance with the first embodiment sharing a plurality of first regions 334 and a plurality of second diffusion regions 330.

In more details about the above structure shown in FIG. 7, a first conductivity type substrate 310, a plurality of second conductivity type well regions 320, each formed in a predetermined portion of the substrate 310, a plurality of gate insulation layers 350 and a plurality of gate electrodes 352 (herein, the gate insulation layers 350 and the gate electrodes 352 configure a plurality of gate structures), each stacked on a selected surface portion of the substrate 310 and separated from the well regions 320 with a predetermined distance; a plurality of first conductivity type first diffusion regions 334, each formed in the respective well region 320 and shared by neighboring transistors, a plurality of second conductivity type second diffusion regions 330, each connected to a ground Vss, formed beneath another selected surface portion of the substrate 310 in one side of the respective gate electrode 352 and shared by neighboring transistors; and a plurality of second conductivity type third diffusion regions 332, each extending from the respective well region 320 to another portion of the substrate 310 in the other side of the respective gate electrode 352 and connected to an input/output pad I/O PAD through a respective resistor 360 are included. A plurality of highly concentrated P-type P⁺ diffusion regions 338 of both edge portions of the substrate 310 are substrate contact regions.

As described above, although the neighboring transistors share the plurality of first diffusion region 334 and the plurality of second diffusion region 330, the LVTSCR structure shown in FIG. 7 obtains the same effect with that obtained in accordance with the first embodiment of the present invention.

Furthermore, each of the first diffusion regions 334 and each of the third diffusion regions 332 may or may not be in contact with each other. The plurality of gate electrodes 352 and the plurality of second diffusion regions 330 are connected to the grounds Vss, and the plurality of first diffusion regions 334 in contact with the plurality of third diffusion regions 332 are directly connected to the input/output pad I/O PAD, while the plurality of third diffusion regions 332 are connected to the input/output pad I/O PAD through the resistors 360. Also, the second diffusion regions and the gate electrodes can be electrically connected to the grounds Vss, and the first diffusion regions can be electrically connected to a power pad. Furthermore, the second diffusion regions and the gate electrodes can be electrically connected to the input/output pad I/O PAD, and the first diffusion regions can be electrically connected to the power pad.

The first conductivity type includes a P-type impurity and the second conductivity type includes an N-type impurity. The second diffusion regions 330 and the third diffusion regions 332 are diffusion regions doped with highly concentrated N-type N⁺ impurities and the first diffusion regions 334 are diffusion regions doped with highly concentrated P-type P⁺ impurities.

In accordance with the third embodiment of the present invention as described above, the third diffusion regions 332 serve a role of the drain of a transistor are connected to the input/output pad I/O PAD through the resistors 360 having a predetermined resistance value, and the first diffusion regions 334 are directly connected to the input/output pad I/O PAD.

The second diffusion regions 330 which are source regions shared by the neighboring transistors are connected to the grounds Vss along with the gate electrodes 352.

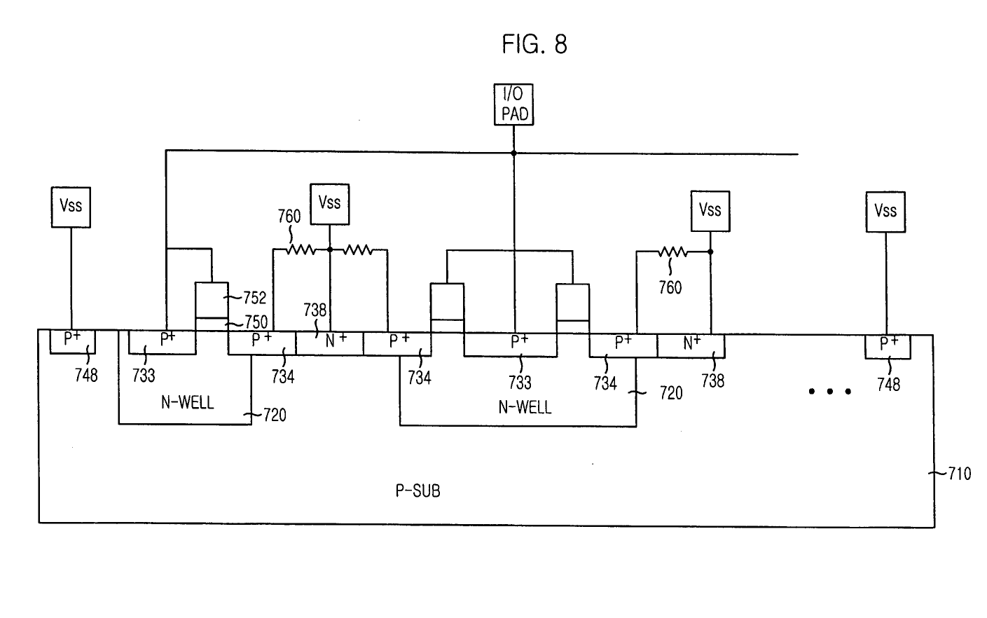

FIG. 8 is a cross-sectional view illustrating an ESD protection circuit having a LVTSCR structure in accordance with a fourth embodiment of the present invention. The same reference numerals used in the second embodiment of the present invention shown in FIG. 6 is used hereinafter.

The fourth embodiment of the present invention shown in FIG. 8 illustrates a structure which a plurality of LVTSCR structures formed in accordance with the second embodiment of the present invention sharing a plurality of second diffusion regions 733 and a plurality of first diffusion regions 738.

As shown in FIG. 8, the ESD protection circuit having the LVTSCR structure in accordance with the fourth embodiment of the present invention includes a first conductivity type substrate 710, a plurality of second conductivity type well regions 720, each formed in a predetermined portion of the substrate 710, a plurality of gate insulation layers 750 and a plurality of gate electrodes 752 (herein, the gate insulation layer 750 and the gate electrode 752 configure gate structures), each stacked on a selected surface portion of the respective well region 720, a plurality of second conductivity type first diffusion regions 738, each formed in the substrate 710, separated from the respective well region 720 with a predetermined distance, connected to the ground Vss and shared by neighboring transistors, a plurality of first conductivity type second diffusion regions 733, each connected to an input/output pad I/O PAD, formed in the respective well region 720 in one side of the respective gate electrode 752 and shared by neighboring transistors, and a plurality of first conductivity type third diffusion regions 734, each being in contact with the respective first diffusion region 738 in the other side of the respective gate electrode 752, extending from the respective well region 720 to another surface portion of the substrate 710 and connected to the respective ground Vss through the respective resistors 760. A plurality of P⁺-type diffusion regions 748 connected to the grounds Vss are substrate contact regions.

Herein, the first diffusion regions 738 and the third diffusion regions 734 may or may not be in contact with each other. The gate electrodes 752 are connected to the input/output pad I/O PAD directly.

The first conductivity type includes a P-type impurity and the second conductivity type includes an N-type impurity. The first diffusion regions 738 are diffusion regions doped with highly concentrated N-type N⁺ impurities, and the second diffusion regions 733 and the third diffusion regions 734 are diffusion regions doped with highly concentrated P-type P⁺ impurities.

In accordance with the fourth embodiment of the present invention as described above, a predetermined portion of the third diffusion regions 734 is formed outside of the well regions 720 and thus, the third diffusion regions 734 corresponding to a drain is connected to the grounds Vss through the resistors 760 having a predetermined value. The first diffusion regions 738 are directly connected to the grounds Vss.

The second diffusion regions 733 corresponding to a source are directly connected to the input/output pad I/O PAD.

The second diffusion regions and the gate electrodes can be connected to a power pad and the first diffusion regions can be connected to an input/output pad I/O PAD. The second diffusion regions and the gate electrodes can be connected to a power pad and the first diffusion regions can be connected to the grounds Vss.

The LVTSCR structure in accordance with the present invention shows both high current conductivity property and a low triggering voltage. Thus, the LVTSCR can be embodied in the ESD protection circuit of high speed, low voltage and high integration semiconductor circuits.

Furthermore, since the LVTSCR structure provides high current conductivity efficiency per unit area, it is possible to obtain the desired ESD protection level with only a small layout area. Also, since junction capacitance of the ESD protection circuit is proportionate with the junction area of a device, it is possible to construct an ESD protection circuit having a low capacitance, thereby making the LVTSCR structure of the present invention suitable for high speed, high density semiconductor integrated circuits.

The present application contains subject matter related to the Korean patent application No. KR 2004-0091537, filed in the Korean Patent Office on Nov. 10, 2004, the entire contents of which being incorporated herein by reference.

While the present invention has been described with respect to certain preferred embodiments, it will be apparent to those skilled in the art that various changes and modifications may be made without departing from the spirit and scope of the invention as defined in the following claims.

What is claimed is:

1. An electrostatic discharge (ESD) protection circuit, comprising:
a first conductivity type substrate;
a second conductivity type well region formed in a predetermined portion of the substrate;
a gate structure including a gate insulation layer and a gate electrode stacked on a selected surface portion of the substrate and separated from the well region with a predetermined distance;
a first conductivity type first diffusion region formed in the well region;
a second conductivity type second diffusion region formed beneath another selected surface portion of the substrate contacting one side edge of the gate structure; and
a second conductivity type third diffusion region, extending from the other side edge of the gate structure into the well region, and electrically connected to the first diffusion region through a resistor.

2. The ESD protection circuit of claim 1, wherein the second conductivity type third diffusion region is formed in one of a structure in contact with the first conductivity type first diffusion region in the well and a structure not in contact with the first conductivity type first diffusion region in the well.

3. The ESD protection circuit of claim 1, wherein a first conductivity type fourth diffusion region is additionally formed in the predetermined portion of the substrate, separated from the well region, and electrically connected to the second diffusion region.

4. The ESD protection circuit of claim 1, wherein the second diffusion region and the gate electrode are electrically connected to the ground, and the first diffusion region is electrically connected to an input/output pad.

5. The ESD protection circuit of claim 1, wherein the second diffusion region and the gate electrode are electrically connected to the ground, and the first diffusion region is electrically connected to a power pad.

6. The ESD protection circuit of claim 1, wherein the second diffusion region and the gate electrode are electrically connected to an input/output pad, and the first diffusion region is electrically connected to a power pad.

7. The ESD protection circuit of claim 1, wherein the resistor is selected from the group consisting of metal, polysilicon and a diffusion region formed in the substrate.

8. The ESD protection circuit of claim 1, wherein the first conductivity type includes a P-type impurity and the second conductivity type includes an N-type impurity.

9. The ESD protection circuit of claim 1, wherein resistance value of the resistor is equal to or larger than 1 Ω.

10. An ESD protection circuit, comprising:
a first conductivity type substrate;
a second conductivity type well region formed in a predetermined portion of the substrate;
a gate structure including a gate insulation layer and a gate electrode stacked on a selected surface portion of the well region;
a second conductivity type first diffusion region formed in the substrate, separated from the well region with a predetermined distance;
a first conductivity type second diffusion region formed in the well region in one side of the gate structure; and
a first conductivity type third diffusion region, extending from the other side edge of the gate structure into the aforementioned well region, and electrically connected to the first diffusion region through a resistor.

11. The ESD protection circuit of claim 10, wherein the first conductivity type third diffusion region is formed in one of a structure in contact with the second conductivity type first diffusion region in the well and a structure non in contact with the second conductivity type first diffusion region in the well.

12. The ESD protection circuit of claim 10, wherein a first conductivity type fourth diffusion region is additionally formed in the predetermined portion of the substrate, separated from the well region, and electrically connected to the first diffusion region.

13. The ESD protection circuit of claim 10, wherein the second diffusion region and the gate electrode are connected to a power pad and the first diffusion region is connected to an input/output pad.

14. The ESD protection circuit of claim 10, wherein the second diffusion region and the gate electrode are connected to a power pad and the first diffusion region is connected to the ground.

15. The ESD protection circuit of claim 10, wherein the second diffusion region and the gate electrode are connected to an input/output pad and the first diffusion region is connected to the ground.

16. The ESD protection circuit of claim 10, wherein the resistor is selected from the group consisting of metal, polysilicon and a diffusion region formed in the substrate.

17. The ESD protection circuit of claim 10, wherein the first conductivity type includes a P-type impurity and the second conductivity type includes an N-type impurity.

18. The ESD protection circuit of claim 10, wherein a resistance value of the resistor is equal to or larger than 1 Ω.

19. An ESD protection circuit, comprising:
a first conductivity type substrate;
a plurality of second conductivity type well regions, each formed in a predetermined portion of the substrate;
a plurality of gate structures, each including a gate insulation layer and a gate electrode formed on a selected surface portion of the substrate and separated from the respective well region with a predetermined distance;
a plurality of first conductivity type first diffusion regions, each formed in the respective well region and shared by neighboring transistors;
a plurality of second conductivity type second diffusion regions, formed beneath another selected surface portion of the substrate in one side of the respective gate structure and shared by neighboring transistors; and
a plurality of second conductivity type third diffusion regions, each extending from the other side edge of the respective gate structure into the respective well region, and electrically connected to the respective first diffusion region through a resistor.

20. The ESD protection circuit of claim 19, wherein each of the second conductivity type third diffusion regions is formed in one of a structure in contact with the respective first conductivity type first diffusion region in the respective well and a structure not in contact with the respective first conductivity type first diffusion region in the respective well.

21. The ESD protection circuit of claim 19, wherein a plurality of first conductivity type fourth diffusion regions are additionally formed in the predetermined portions of the substrate, separated from the well regions, and electrically connected to a portion of the second diffusion regions.

22. The ESD protection circuit of claim 19, wherein the second diffusion regions and the gate electrodes are electrically connected to the grounds, and the first diffusion regions are electrically connected to an input/output pad.

23. The ESD protection circuit of claim 19, wherein the second diffusion regions and the gate electrodes are electrically connected to the grounds, and the first diffusion regions are electrically connected to a power pad.

24. The ESD protection circuit of claim 19, wherein the second diffusion regions and the gate electrodes are electrically connected to an input/output pad, and the first diffusion regions are electrically connected to a power pad.

25. The ESD protection circuit of claim 19, wherein the resistor is selected from the group consisting of metal, polysilicon and a diffusion region formed in the substrate.

26. The ESD protection circuit of claim 19, wherein the first conductivity type includes a P-type impurity and the second conductivity type includes an N-type impurity.

27. The ESD protection circuit of claim 19, wherein a resistance value of the resistor is equal to or larger than 1 Ω.

28. An ESD protection circuit, comprising:
a first conductivity type substrate;
a plurality of second conductivity type well regions, each formed in a predetermined portion of the substrate;
a plurality of gate structure including a gate insulation layer and a gate electrode formed on a selected surface portion of the respective well region;
a plurality of second conductivity type first diffusion regions, each formed in the substrate, separated from the respective well region with a predetermined distance, shared by neighboring transistors and connected to a respective ground;
a plurality of first conductivity type second diffusion regions, each connected to an input/output pad, formed in the respective well region in one side of the respective gate structure and shared by neighboring transistors; and
a plurality of first conductivity type third diffusion regions, each extending from the other side edge of the respective gate structure into the respective well region, and electrically connected to the respective first diffusion region through a resistor.

29. The ESD protection circuit of claim 28, wherein each of the first conductivity type third diffusion regions is formed in one of a structure in contact with the second conductivity type first diffusion region in the well and a structure not in contact with the second conductivity type first diffusion region in the well.

30. The ESD protection circuit of claim 28, wherein a plurality of first conductivity type fourth diffusion regions are additionally formed in the predetermined portion of the substrate, separated from the well regions, and electrically connected to a portion of the first diffusion regions.

31. The ESD protection circuit of claim 28, wherein the second diffusion regions and the gate electrodes are connected to a power pad and the first diffusion regions are connected to an input/output pad.

32. The ESD protection circuit of claim 28, wherein the second diffusion regions and the gate electrodes are connected to a power pad and the first diffusion regions are connected to the grounds.

33. The ESD protection circuit of claim 28, wherein the second diffusion regions and the gate electrodes are connected to an input/output pad and the first diffusion regions are connected to the grounds.

34. The ESD protection circuit of claim 28, wherein the resistor is selected from the group consisting of metal, polysilicon and a diffusion region formed in the substrate.

35. The ESD protection circuit of claim 28, wherein the first conductivity type includes a P-type impurity and the second conductivity type includes an N-type impurity.

36. The ESD protection circuit of claim 28, wherein a resistance value of the resistor is equal to or larger than 1 Ω.
